(19) United States
(12) Patent Application Publication
(10) Pub. No.: US 2009/0052129 A1
(43) Pub. Date: Feb. 26, 2009

(54) Housing of Electronic Device and Fabricating Method Thereof

(75) Inventor: Sheng-Yu Tsai, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASUSTEK COMPUTER INC., Taipei (TW)

(21) Appl. No.: 12/181,109

(22) Filed: Jul. 28, 2008

(30) Foreign Application Priority Data
Aug. 23, 2007 (TW) 96131300

(51) Int. Cl. H05K 5/00; B32B 17/04; B29C 45/00

(52) U.S. Cl. 361/681; 264/328.1; 428/35.6

(57) ABSTRACT

A method for fabricating a housing of an electronic device is provided. The method includes the steps of providing a bamboo laminate first, forming a recess on the bamboo laminate, performing an embedding injection molding process to form a supporting element made of high polymer in the recess and performing a cutting step to cut the bamboo laminate to have a predetermined thickness.

This application claims priority to Taiwan Application Serial Number 96131300, filed Aug. 23, 2007, which is herein incorporated by reference.

### BACKGROUND OF THE INVENTION

1. Field of the Invention

The invention relates to a method for fabricating a housing of an electronic device and, more particularly, to a method for fabricating a housing of an electronic device and an electronic device utilizing the same.

2. Description of the Related Art

Housings of common electronic products on the market mostly are made of plastic or metal. The fault of plastic housings is that the plastic sense of products is too heavy, and noble and unique product characteristics cannot be shown. Since the environmental protection problem is valued now, the development space of plastic products becomes smaller and smaller. Since the specific heat capacity of metal housings is low, the metal housings make cold impressions on users.

A bamboo laminate is a large-sized bamboo timber made by gluing small-sized primitive bamboo plates together along a wood grain direction. The made bamboo laminate cannot be easily deformed or broken, and it has more elasticity and bending strength than primitive bamboo does. In the conventional technology, bamboo laminate slices are utilized to cover outside surfaces of components in a slice-veneering manner to form the components with wood grain.

It is often hard to apply slice-veneering technology to an uneven surface, and the bamboo material is easy to be warped or deformed after a slicing processing. After long term usage, the bamboo material often peels off because of aging of adhesives, and it cannot be closely combined with components made of other materials. The slice-veneering manner is complex and time-consuming, and the beauty sense of the transection of the bamboo material and the warm feel of the bamboo material different from the cold metal cannot be shown.

### BRIEF SUMMARY OF THE INVENTION

The invention provides a method for fabricating a housing of an electronic device, and the method decreases the complexity of a fabricating process and gives consideration to both the beauty sense of wood grain and a long lifespan.

A method for fabricating a housing of an electronic device in the invention at least includes the step of providing a bamboo laminate. Next, a recess is formed on the bamboo laminate. Finally, an embedding injection molding process is performed to form a supporting component made of high polymer in the recess, and a cutting step is performed to cut the bamboo laminate to a predetermined thickness.

According to another objective of the invention, a housing of an electronic device is provided. The housing at least includes a bamboo laminate and a supporting component made of high polymer. The high polymer is mixed with mineral fiber or fiberglass. The bamboo laminate and the supporting component are closely combined in an embedding injection molding manner to form the housing. The supporting component is covered by the bamboo laminate, and part of the supporting component penetrates into fiber chinks of the bamboo laminate.

According to another objective of the invention, an electronic device is provided. The electronic device at least includes a body, a display unit and a housing. The display unit is connected to the body, and the housing covers the display unit. The housing further includes a bamboo laminate and a supporting component made of high polymer. The supporting component made of high polymer is located between the bamboo laminate and the display unit, and part of the supporting component made of high polymer penetrates into fiber chinks of the bamboo laminate.

From the above, the technology utilizing the embedding injection molding process to fabricate the housing allows the supporting component to be directly formed on the bamboo laminate, and it also can be put into practice on a non-even surface to increase the utility of products in addition to greatly saving manpower and decreasing the cost. High polymer used to fabricate the supporting component such as plastic material can be closely embedded into the xylem of the bamboo laminate to increase the strength of the sliced bamboo material.

### BRIEF DESCRIPTION OF THE SEVERAL VIEWS OF THE DRAWINGS

These and other features, aspects, and advantages of the present invention will become better understood with regard to the following description, appended claims, and accompanying drawings.

FIG. 1A and FIG. 1B are schematic diagrams showing a notebook computer having a housing made of a bamboo laminate according to one embodiment of the invention;

FIG. 2A is a three-dimensional schematic diagram showing a provided bamboo laminate according to one embodiment of the invention;

FIG. 2B is a schematic diagram showing a milling step according to one embodiment of the invention;

FIG. 2C is a schematic diagram showing steps of an embedding injection molding process according to one embodiment of the invention;

FIG. 2D is a sectional view along an AA′ direction in FIG. 2C;

FIG. 2E is a schematic diagram showing a joining component according to one embodiment of the invention;

FIG. 2F is a schematic diagram showing a cutting step according to one embodiment of the invention; and

FIG. 2G is a schematic diagram showing that a medium film layer is provided into the recess of a bamboo laminate according to one embodiment of the invention.

### DETAILED DESCRIPTION OF THE EMBODIMENTS

The spirit of the invention will become better understood with regard to the following description and accompanying drawings, and after persons having ordinary skill in the art understand embodiments of the invention, they may make various modifications and changes without departing from the scope and spirit of the invention.

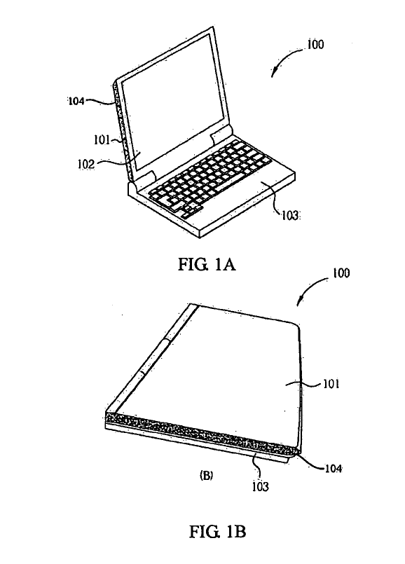

A housing of a notebook computer is taken as an example to illustrate a method for fabricating the housing hereinbelow. FIG. 1A and FIG. 1B are schematic diagrams showing a notebook computer having a housing made of a bamboo laminate according to one embodiment of the invention. As shown in FIG. 1A and FIG. 1B, a notebook computer 100 has a housing 101, a display unit 102 and a body 103. The housing 101 covers the display unit 102 electrically connected to the body 103, and the body 103 may have an input unit (such as a keyboard in FIG. 1A).

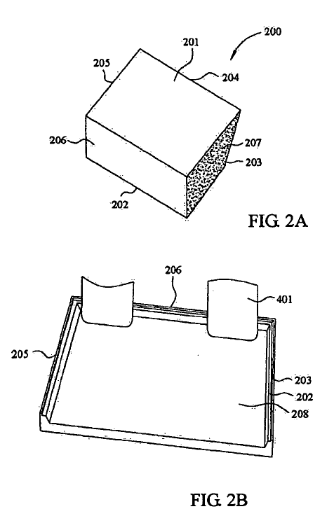

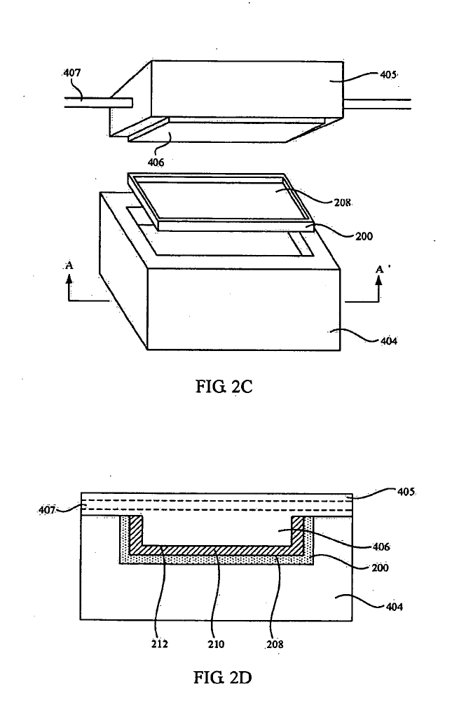

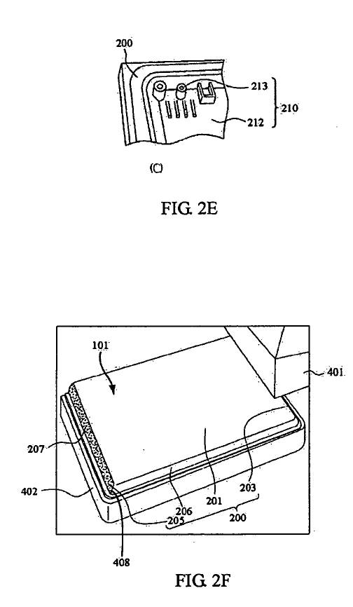

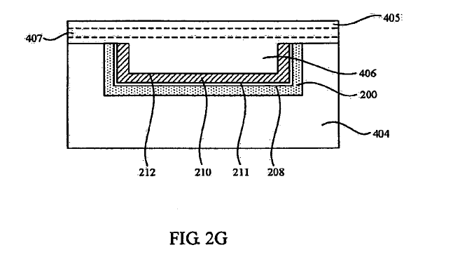

The above housing 101 mostly consists of a bamboo laminate 104 and a supporting component (no shown). The supporting component is located between the bamboo laminate 104 and the display unit 102, and the bamboo laminate 104 appears natural bamboo grains. The method for fabricating the housing 101 of the notebook computer 100 is illustrated hereinbelow. To further illustrate steps of the method, the steps are illustrated with FIGS. 2A to 2D hereinbelow.

The process of fabricating the housing includes the steps hereinbelow. A bamboo laminate is provided first. As shown in FIG. 2A, a provided bamboo laminate 200 includes a first surface 201, a second surface 202, a first circumferential surface 203, a second circumferential surface 204, a third circumferential surface 205 and a fourth circumferential surface 206. The first surface 201, the second surface 202, the second circumferential surface 204 and the fourth circumferential surface 206 appear longitudinal grains of the bamboo because of the natural characteristic of a laminate. The first circumferential surface 203 and the third circumferential surface 205 appear transaction grains of the bamboo and dot-shaped bamboo vessels 207. The vessels 207 are natural structures owned by the bamboo laminate 200 and are natural grains which cannot be appeared in an ordinary slice-veneering manner. The above bamboo laminate can be formed by a carbonized bamboo, a non-carbonized bamboo or a bamboo laminate which is partially carbonized.

Next, a recess is formed on the bamboo laminate. As shown in FIG. 2B, in the embodiment, the recess is formed in the bamboo laminate in a milling mode. A milling cutter 401 of a computer numerical control (CNC) machine can be utilized to mill the second surface 202 of the bamboo laminate 200 to form a recess 208. The first circumferential surface 203, the third circumferential surface 205 and the fourth circumferential surface 206 of the bamboo laminate 200 are reserved. The second circumferential surface 204 of the bamboo laminate 200 is milled away, thereby providing the space for a connecting hinge connected to an electronic device.

Afterward, a supporting component is formed in the recess of the bamboo laminate by an embedding injection molding process. The called embedding injection molding is also named a plug-in module molding. The molding manner is that a main component is placed into a mold, and then plastic material are ejected from the mold to form a plastic layer on the main component during an injection molding process. Steps of the embedding injection molding process are illustrated with FIG. 2C and FIG. 2D. Wherein, FIG. 2C is a schematic diagram showing steps of an embedding injection molding process, and FIG. 2D is a sectional view along an AA′ direction in FIG. 2C.

As shown in FIG. 2C, the milled bamboo laminate 200 is placed in a female mold 404 by the way that the recess 208 faces away from the female mold 404. Then, the bamboo laminate 200 is covered with a male mold 405, and the protrudent portion 406 of the male mold 405 is located in the recess 208. Next, plastic material is injected into the space between the recess 208 and the protrudent portion 406 to form a supporting component 210 in the recess 208. To decrease the high temperature during the embedding injection molding process, cool water can be injected into a pipeline 407 disposed in the male mold 405. When the cool water flows through the interior of the male mold 405, it can dissipate the heat for the molded supporting component 210.

As shown in FIG. 2E, the protrudent portion 406 of the male mold 405 may have a plurality of joining components molds (now shown) to form a plurality of joining components 213 disposed on the exposed surface 212 of the fabricated supporting component 210. FIG. 2E is partial enlarged drawing showing the joining component 213. The exposed surface 212 of the supporting component 210 has a plurality of joining components 213 for connecting the supporting component 210 to the display unit or other components (not shown) in subsequent assemblage.

The embedding injection molding process is performed in a high temperature state. As a result, the water capacity of the bamboo laminate not only affects the temperature during the process, but also is related to the problem that whether the bamboo laminate may be brittle, crackled, and fractured after the embedding injection molding process. In the embodiment, the water capacity of the bamboo laminate is maintained at 10 to 13 degrees. To avoid causing the bamboo laminate 200 to be warped or deformed after the embedding injection molding process, the thickness of the bamboo laminate is preferred to be about 3 to 5 mm after the milling process.

The material used in the embedding injection molding process may be high polymer such as plastic material. To improve the material characteristic or meet different requirements, mineral fiber or fiberglass may be added to the plastic material, and the addition ratio may be about 20-30 wt % of high polymer. Since the molecule of the plastic material is small, and the plastic material is liquid in a high temperature state, the plastic material penetrates into fiber chinks of the bamboo laminate (such as chinks in vessel structures) to form the supporting component closely embedded into the bamboo laminate.

Finally, the surface of the bamboo laminate is cut to obtain a predetermined thickness. FIG. 2F is a schematic diagram showing that the bamboo laminate is cut. In FIG. 2F, the bamboo laminate 200 is placed on the mold 402 with the supporting component 210 facing the mold 402 to fix and support the bamboo laminate 200. Next, the milling cutter 401 of the CNC machine cuts the first surface 201 of the bamboo laminate 200 to allow the bamboo laminate 200 to have a predetermined thickness which may be about 0.3 to 1.5 mm. In the embodiment, the predetermined thickness is 0.6 mm to 1.0 mm to maintain the slimness and lightness of the electronic device, and a protection effect is given consideration. Edges of the bamboo laminate 200 can be cut to form a right angle or an oblique angle 408 with a predetermined obliquity according to a requirement. As shown in FIG. 2F, with the oblique angle 408, the edges of the housing 101 can be smoother, and a natural transection of the bamboo laminate is much clear.

After the above steps, the housing fabricated with the bamboo laminate 200 can cover periphery of the supporting component 210 properly and completely. Thus, the supporting component 210 cannot be easily seen from the appearance, and it increases the strength of the bamboo laminate 200 which is cut to be thin. The joining components 213 are utilized to assemble the housing and the display unit of the notebook computer, and then a finished product shown in FIG. 1B is obtained.

Since the plastic material is ejected in a high speed and temperature state, and the bamboo laminate itself cannot endure high pressure and high heat, the bamboo laminate 200 covered by the plastic material may have a deformed shape which cannot be seen. Furthermore, the flatness of the bamboo laminate 200 cannot be controlled, so part of the bamboo laminate 200 may be completely milled to allow part of the supporting component 210 to be exposed outside. It affects the appearance when the first surface 201 of the bamboo laminate 200 is milled (as shown in FIG. 2F) after the injection molding step.

To avoid the above condition, as shown in FIG. 2Q before the high speed injection molding process, a medium film layer 211 is attached to the interior surface of the recess 208 of the bamboo laminate 200 first. Then, the injection molding process is performed to allow the medium film layer 211 to be located between the supporting component 210 and the bamboo laminate 200. The bamboo laminate 200 is protected from being warped or deformed during the high speed injection molding process.

The material of the medium film layer 211 in the above embodiment is not limited and is preferred to be the material having characteristics of pressure resistance and heat resistance. For example, the material can be polycarbonate (PC), polyethylene terephthalate (PET) (such as PET which is manufactured by the Dupont corporation and is named Mylar Film), or metal foil (such as aluminum foil) and so on. The thickness of the medium film layer 211 is about 0.3 to 0.8 mm and can be fine adjusted according to the quantity of the plastic material during the injection molding process. Generally speaking, the needed thickness of the medium film layer 211 increases along with the increase of the quality of the plastic material. If the two surfaces of the medium film layer 211 are both coated with gum at advance, it helps the medium film layer 211 to be attached and fixed to the supporting component 210 or the bamboo laminate 200.

Shapes and sizes of the bamboo laminate 200 and the supporting component 210 in the embodiment are only examples of the invention, and they does not limit the scope of the invention. In other words, the bamboo laminate 200 and the supporting component 210 may also have other possible shapes and sizes without departing from the spirit of the invention. Although the electronic device in the embodiment is the notebook computer, any electronic devices (such as a mobile phone, an optical drive, etc.) having housings can be made to be electronic devices with bamboo appearances by the fabricating method disclosed by the invention.

To sum up, the technology for fabricating the housing by the embedding injection molding process is different from the conventional slice-veneering manner. It allows the supporting component to be directly formed on the bamboo laminate to decrease the complexity of the process and is suitable to mass production. Since the plastic material for fabricating the supporting component penetrates into vessel structures of the xylem of the bamboo material, the support component and the bamboo material can be closely attached to each other. The bamboo material does not peels off after long term usage. If a user wants to mill the bamboo laminate to be thinner, he can add the medium film layer 211 to protect the bamboo laminate from being deformed during the injection molding process. If two surfaces of the medium film layer 211 are both coated with gum at advance, it is helpful to the combination of the medium film layer 211 and the plastic.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A method for fabricating a housing of an electronic device, the method comprising the steps of:
providing a bamboo laminate;
forming a recess on the bamboo laminate;
performing an embedding injection molding process to form a supporting component made of high polymer in the recess; and
performing a cutting step to cut the bamboo laminate to a predetermined thickness.

2. The method according to claim 1, wherein the step of performing the embedding injection molding process comprises the steps of:
placing the bamboo laminate into a female mold, wherein the recess on the bamboo laminate faces away from the female mold;
covering with a male mold to allow a protrudent portion of the male mold to be correspondingly located in the recess; and
injecting high polymer into the space between the recess and the protrudent portion to form the supporting component in the recess.

3. The method according to claim 1, wherein the high polymer is mixed with mineral fiber or fiberglass.

4. The method according to claim 3, wherein the addition ratio of the mineral fiber or fiberglass is 20-30 wt % of the high polymer.

5. The method according to claim 1, wherein a computer numerical control (CNC) machine performs the cutting step and a milling step.

6. The method according to claim 1, wherein the thickness of the bamboo laminate is 3 to 5 mm after the cutting step.

7. The method according to claim 1, the inside of the recess of the bamboo laminate further comprises a medium film layer.

8. The method according to claim 7, wherein the thickness of the medium film layer is 0.3 to 1.5 mm.

9. The method according to claim 7, wherein the medium film layer is selected from a group consisting of polycarbonate (PC), polyethylene terephthalate (PET) and aluminum foil.

10. A housing of an electronic device, the housing comprising:
a bamboo laminate; and
a supporting component made of high polymer and covered with the bamboo laminate;
wherein the high polymer is mixed with mineral fiber or fiberglass, and the bamboo laminate and the supporting component are closely combined to form the housing in an embedding injection molding mode.

11. The housing according to claim 10, wherein the addition ratio of the mineral fiber or fiberglass is 20-30 wt % of the high polymer.

12. The housing according to claim 10 further comprising a medium film layer disposed between the bamboo laminate and the support component.

13. The housing according to claim 12, wherein the thickness of the medium film layer is 0.3 to 1.5 mm.

14. The housing according to claim 12, wherein the medium film layer is selected from a group consisting of polycarbonate (PC), polyethylene terephthalate (PET) and aluminum foil.

15. An electronic device comprising:
a body;
a display unit connected to the body; and
a housing covering the display unit and comprising:
a bamboo laminate; and
a supporting component made of high polymer located between the bamboo laminate and the display unit;
wherein the high polymer is mixed with mineral fiber or fiberglass, and the bamboo laminate and the supporting component are closely combined to form the housing in an embedding injection molding mode.

16. The electronic device according to claim 15 further comprising a medium film layer disposed between the bamboo laminate and the supporting component.

17. The electronic device according to claim 16, wherein the thickness of the medium film layer is 0.3 to 1.5 mm.

18. The electronic device according to claim 16, wherein the medium film layer is selected from a group consisting of polycarbonate (PC), polyethylene terephthalate (PET) and aluminum foil.
